(19) United States
(12) Patent Application Publication
(10) Pub. No.: US 2005/0280088 A1
(43) Pub. Date: Dec. 22, 2005

(54) Backside body contact

(76) Inventors: Byoung W. Min, Austin, TX (US); Scott K. Pozder, Austin, TX (US); Hector Sanchez, Cedar Park, TX (US)

Correspondence Address: FREESCALE SEMICONDUCTOR, INC.;LAW DEPARTMENT, 7700 WEST PARMER LANE MD:TX32/PL02, AUSTIN, TX, 78729, US

(21) Appl. No.: 10/872,025

(22) Filed: Jun. 18, 2004

(51) Int. Cl. H01L 27/01

(52) U.S. Cl. 257/347

(57) ABSTRACT

A back side body contact for a transistor that extends through an opening in an insulating layer located adjacent to the backside of the body. The backside contact is coupled to an interconnect on the backside. In some examples, the interconnect is coupled to an interconnect located with respect the other side of an active layer which is coupled to a body voltage bias source.

### BACKGROUND OF THE INVENTION

1. Field of the Invention

This invention relates in general to semiconductor devices and in particular to a backside body contact.

2. Description of the Related Art

With some integrated circuits, it may be important to bias the body of a transistor. For example, with some transistors, it may be desirable to ground the body. With other transistors, it may be beneficial to change the body bias during operation e.g. such as for transistors used in memory arrays or other transistors where it is desirable to change the threshold voltage during operation. Still with other transistors (e.g. transistors having a semiconductor on insulator (SOI) configuration), biasing the body may reduce a transient circuit effect from a floating body voltage.

What is desirable is a new way to bias the body of a transistor.

### BRIEF DESCRIPTION OF THE DRAWINGS

The present invention may be better understood, and its numerous objects, features, and advantages made apparent to those skilled in the art by referencing the accompanying drawings.

FIG. 1 is a partial side cross-sectional view of an embodiment of a wafer during a stage in its manufacture according to the present invention.

FIG. 2 is a partial side cross-sectional view of an embodiment of a wafer during another stage in its manufacture according to the present invention.

FIG. 3 is a partial side cross-sectional view of an embodiment of a wafer during another stage in its manufacture according to the present invention.

FIG. 4 is a partial side cross-sectional view of an embodiment of a wafer during another stage in its manufacture according to the present invention.

FIG. 5 is a partial side cross-sectional view of an embodiment of a wafer during another stage in its manufacture according to the present invention.

FIG. 6 is a partial side cross-sectional view of an embodiment of a wafer during another stage in its manufacture according to the present invention.

FIG. 7 is a partial side cross-sectional view of an embodiment of a wafer during another stage in its manufacture according to the present invention.

FIG. 8 is a partial side cross-sectional view of an embodiment of a wafer during another stage in its manufacture according to the present invention.

FIG. 9 is a partial side cross-sectional view of an embodiment of a wafer during another stage in its manufacture according to the present invention.

The use of the same reference symbols in different drawings indicates identical items unless otherwise noted. The figures are not necessarily drawn to scale.

### DETAILED DESCRIPTION

The following sets forth a detailed description of a mode for carrying out the invention. The description is intended to be illustrative of the invention and should not be taken to be limiting.

FIGS. 1-9 set forth partial cross sectional side views of various stages of the manufacture of a transistor with a back side body contact according to one embodiment of the present invention.

FIG. 1 is a partial cross sectional side view of wafer 101. Wafer 101 includes multiple transistors for multiple integrated circuits, wherein transistor 115 is shown in FIG. 1. In one embodiment, transistor 115 is a field effect transistor and may be either a P-type transistor or N-type transistor depending upon the body and source/drain doping. Wafer 101 includes a substrate 103 with an insulator layer 105 (e.g. SiO₂) located there over. An active layer 107 is located over insulator layer 105. In the embodiment shown, active layer 107 includes a layer of semiconductor material (e.g. silicon, silicon germanium, or layers of different semiconductor materials) in which the active regions (e.g. active region 106) of transistors of wafer 101 are formed. In FIG. 1, transistor 115 includes active region 106. Formed within active layer 107 are isolation regions (e.g. 127) which are used to isolate the active regions (e.g. 106) of the transistors in layer 107. Layer 107 includes an isolation region 131.

In the embodiment shown, active region 106 includes two source/drain regions 111 and 113 and a body region 109 located there between. In the embodiment shown, source/drain regions 111 and 113 are doped to be a first conductivity type (e.g. N-type or P-type) and body 109 is doped to be of a second conductivity type (the other of N-type or P-type). Body 109 includes a channel region located beneath gate 117.

A gate/contact layer 108 is locate over active layer 107. Gate/contact layer includes gates (e.g. gate 117 of transistor 115), source/drain contacts (e.g. source/drain contacts 121 and 119 of transistor 115) and gate contacts (e.g. gate contact 118 of transistor 115) of transistors having their active regions in layer 107. Layer 108 also includes dielectric material for desired electrical isolation of the conductive structures of layer 108 and adjacent layers. The gates (e.g. 117) and source/drain regions (e.g. 111 and 113) may include silicided portions (not shown) contacting its respective gate or source/drain contact.

A metal 1 interconnect layer 123 is located over layer 108. Layer 125 represents one or more additional metal interconnect layers (e.g. metal interconnect layers 2-9 in one embodiment) located over layer 108. The metal interconnect layers in layer 123 and layer 125 include metal interconnects (e.g. 134) and vias (not shown in layers 123 and 125 of FIG. 1) for electrically coupling the source/drain regions, gates, and other structures of wafer 101 to each other and to external conductive structures. The metal interconnects of layer 125 are not shown in the Figures. In one embodiment, the metal interconnects may include copper, aluminum or gold, but may be made of other conductive material (e.g. doped polysilicon) in other embodiments. Each of the interconnects, vias, and contacts of wafer 101 may include barrier layers (not shown) of e.g. titanium, titanium nitride, tantalum, and/or tantalum nitride. The metal interconnect layers in the embodiment shown also include interlevel dielectrics for electrical isolation of the conductive structures. In the embodiment shown, a passivation layer 137 is located over layer 125.

In the embodiment shown, layer 123 includes an interconnect 133 coupled to a body bias source (not shown). In one embodiment, the body bias source is coupled to a supply voltage (e.g. at a ground or non ground voltage). In other embodiments, the voltage of the body bias source may be varied during operation to bias body 109 at different voltages during operation.

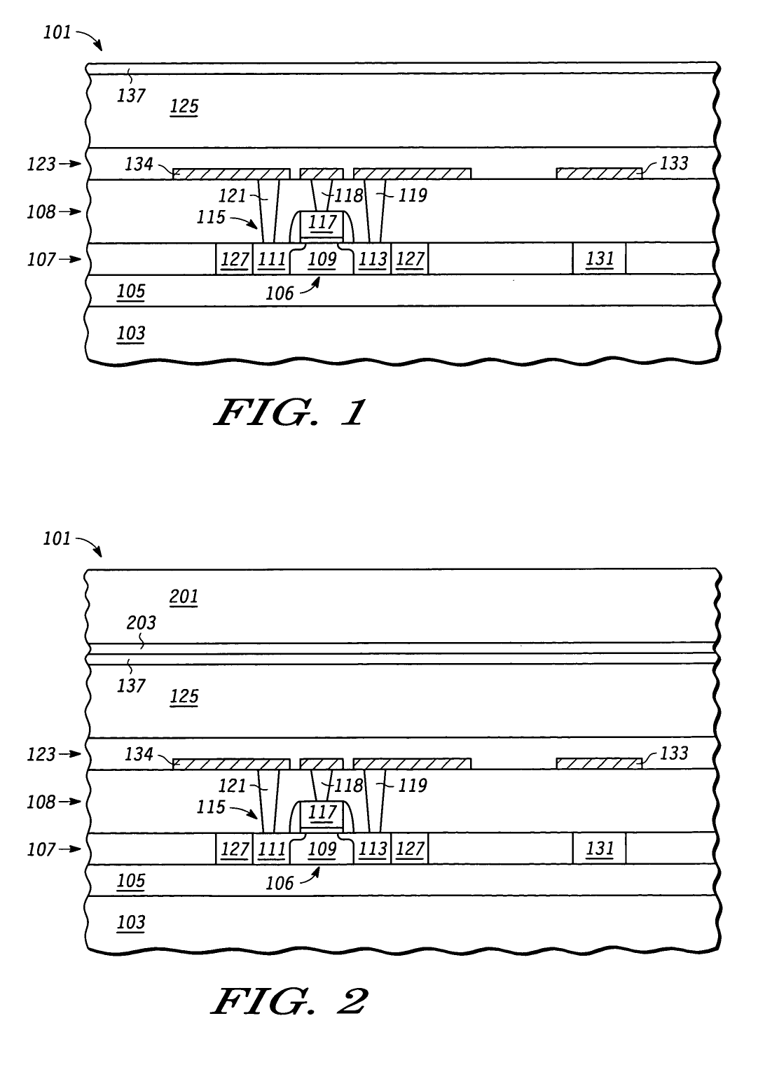

FIG. 2 shows a partial cross sectional view of wafer 101 after a substrate 201 is bonded to passivation layer 137 with bond layer 203. In some embodiments, bond layer 203 includes an organic glue e.g. benzocyclobutene, but may include other materials in other embodiments. In one embodiment, substrate 201 is made of bulk silicon, but may be made of other materials in other embodiments.

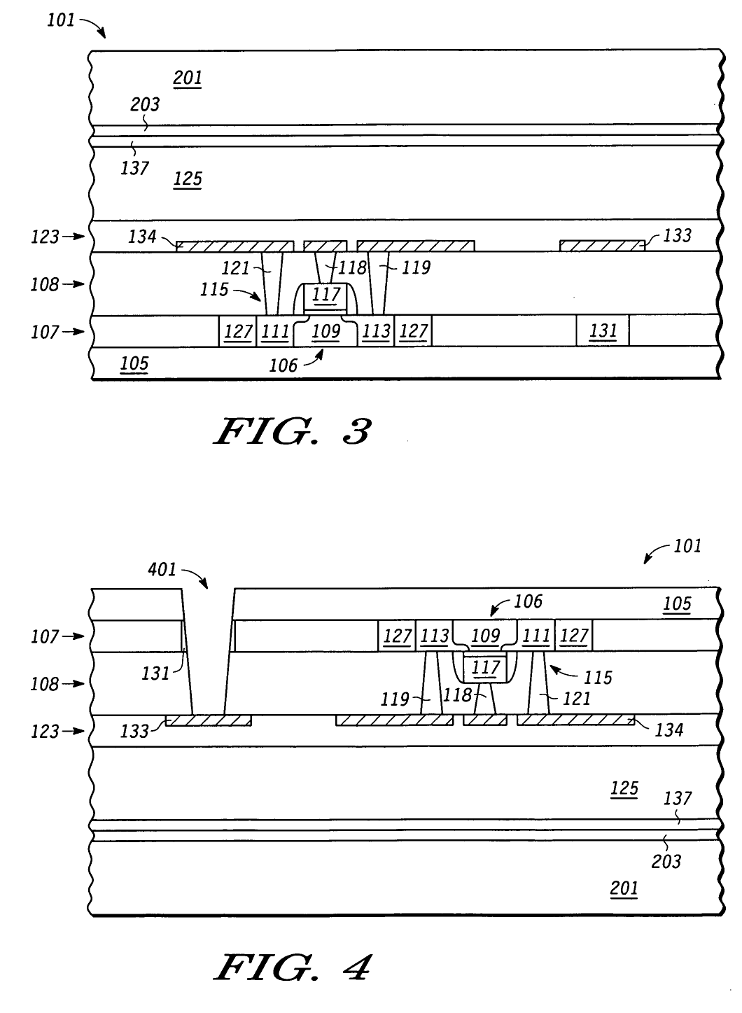

FIG. 3 shows a partial cross sectional side view of wafer 101 after substrate 103 has been removed. In one embodiment, substrate 103 maybe removed by e.g. wafer grinding of all but about 50 microns of substrate 103 with the remaining portion being removed by a highly selective silicon to oxide etch (e.g. tetramethylammonioum hydroxide (TMAH)).

FIG. 4 shows a partial cross sectional view of wafer 101. After substrate 103 is removed, wafer 101 is then turned over for further processing on the backside. In the embodiment shown, an opening 401 has been formed through layer 105, isolation region 131, and the dielectric material of layer 108 to interconnect 133. In one embodiment, opening 401 is formed by patterning a mask (not shown) followed by an etch. In other embodiments, layer 108 may include a conductive structure such as e.g. a contact structure (not shown) wherein the opening would be formed to the conductive structure.

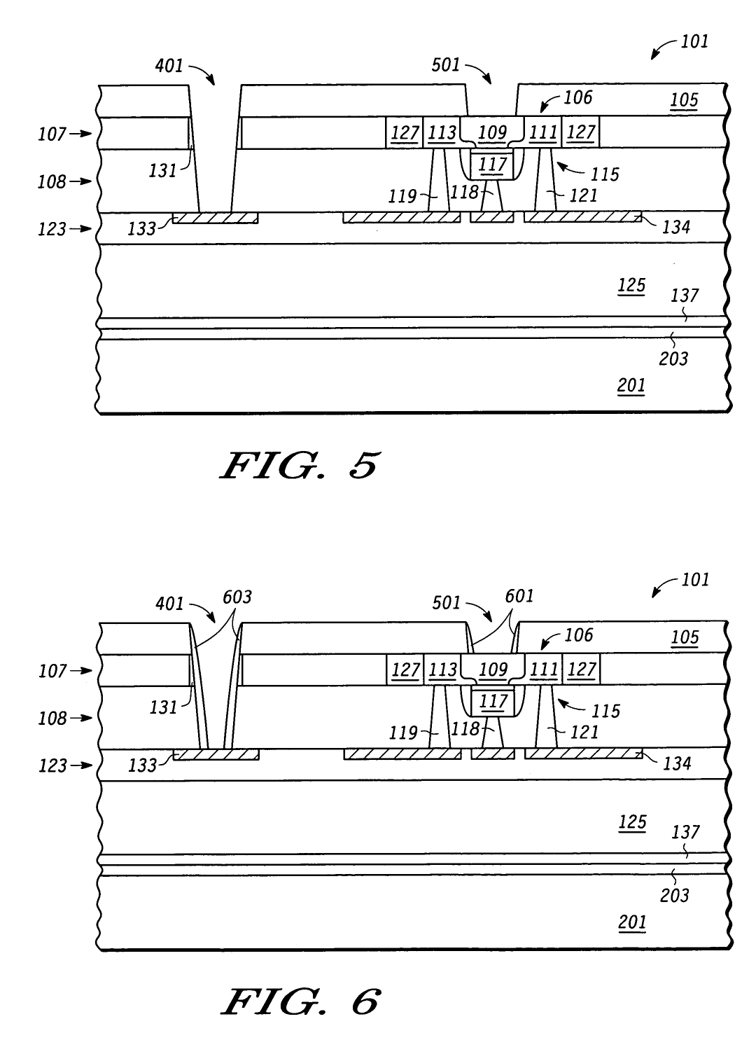

Referring to FIG. 5, an opening in layer 105 is formed to body 109. In one embodiment, opening 109 is formed by patterning a mask (not shown) followed by a subsequent etching of layer 105. However, opening 501 may be made by other processes in other embodiments. In one embodiment, the etchant is highly selective with respect to the material of body 109.

In other embodiments, openings 401 and 501 are formed with the same mask and etching. However, forming them separately may, in some embodiments, reduce the crystal damage to active region 106.

Referring to FIG. 6, in the embodiment shown, sidewall spacer 603 is formed in opening 401 and sidewall spacer 601 is formed in opening 501. In one embodiment, spacers 601 and 603 are formed by depositing a layer of dielectric material (e.g. SiO₂) over the backside of wafer 101 (relative to the view shown in FIG. 6) followed by an isotropic etch of the layer. In some embodiments, spacers 603 and 601 would extend only partway up (relative to the view shown in FIG. 6) openings 501 and 401, respectively. In some embodiments, spacer 601 may effectively reduce the amount of body 109 that comes in contact with conductive material to be later filed in opening 501. In some embodiments, spacer 601 may advantageously reduce the possibility that the conductive material in opening 501 contacts source/drain region 111 or source/drain region 113. In other embodiments, no spacers are formed in opening 501.

In some embodiments, a dopant of the same conductivity type as body 109 may be implanted into body 109 before or after forming sidewall spacer 601 to ensure that the conductive material in opening 501 does not contact a source/drain region of transistor 115. Thus, if opening 501 were to become misaligned and expose a portion of source/drain region 111 or region 113, then the dopant from this doping would transform that portion of the source/drain region to a portion of the body of the transistor.

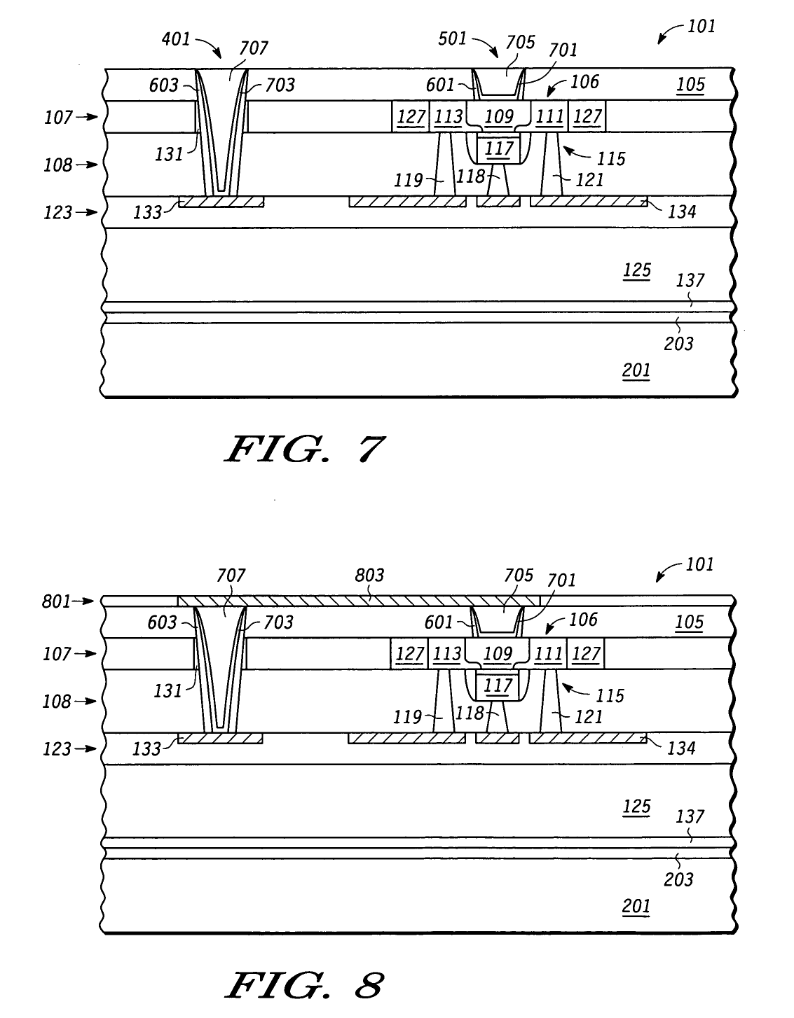

FIG. 7 shows wafer 101 after barrier layers 703 and 701 are formed in openings 401 and 501 respectively and conductive fill material 707 and 705 is formed in openings 401 and 501 respectively. In some embodiments, the barrier layers include e.g. titanium, titanium nitride, tantalum, and/or tantalum nitride. In some embodiments, barrier layers 703 and 701 include multiple layers of different barrier layer material. In some embodiments, fill material 707 and 705 is tungsten, but may include other conductive materials in other embodiments.

In one embodiment, a layer (or layers) of barrier material is deposited (e.g. by chemical vapor deposition (CVD) or by physical vapor deposition) over wafer 101 including in openings 401 and 501 wherein the layer of barrier material physically contacts interconnect 133 and body 109. In some embodiments, a silicide (not shown) of e.g. of cobalt or nickel may be formed on body 109 prior to the deposition of the barrier material. A layer of conductive fill material is then deposited over the layer of barrier material, wherein the back side of wafer 101 is subject to a chemical mechanical polish (CMP) using layer 105 as a polishing stop. The conductive structure in openings 401 and 501 maybe formed by other techniques and/or may be made of other materials in other embodiments. In some embodiments, the openings may not include a barrier layer.

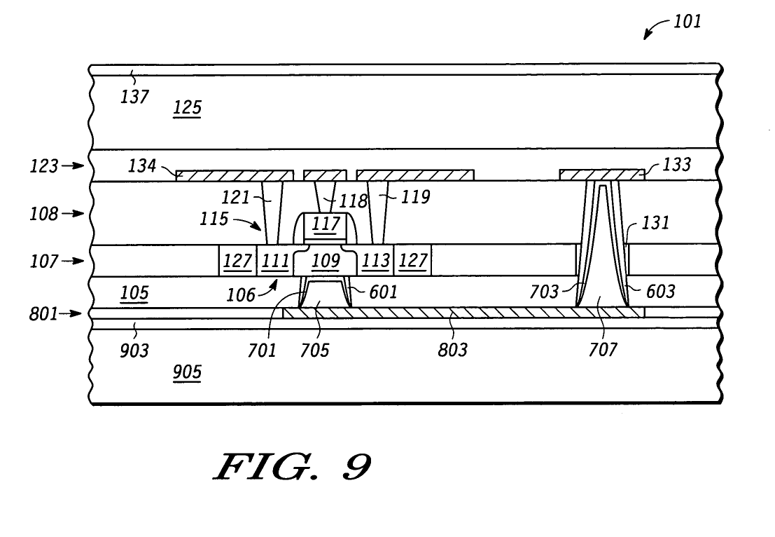

FIG. 8 shows a view of wafer 101 after a metal interconnect layer 801 is formed over the backside. Layer 801 includes a metal interconnect 803 that electrically couples fill material 705 to fill material 707 to couple interconnect 133 to body 109. Layer 105 also includes dielectric material. In some embodiments, interconnect 803 is made of copper, gold or aluminum, but may be made of other materials in other embodiments. In some embodiments, interconnect 803 may include a barrier layer (not shown).

In some embodiments, other metal interconnect layers (not shown) maybe formed over metal interconnect layer 801. These other metal interconnect layers may include metal interconnects and vias coupled to transistors having active regions in layer 107. With some of these embodiments, other conductive structures may extend through layer 105. In some embodiments, external connectors or bond pads may be formed on the back side of wafer 101 over layer 801. In one embodiment, interconnect 803 may be coupled to the body of other transistors.

FIG. 9 shows a view of wafer 101 which is inverted from the view shown in FIG. 8. In the embodiment shown, after forming interconnect layer 801, a substrate 905 is bonded to layer 801 with bond layer 903. Afterwards, substrate 201 and bond layer 203 are removed. In one embodiment, all but 50 microns of substrate 201 is removed by wafer grinding with the last portion being removed by a TMAH etch. Bond layer 203 is then removed with e.g. a dry etch of a oxygen-CF₄ plasma.

In some embodiments, other metal interconnect layers maybe formed over layer 125 after substrate 201 has been removed.

Other processing steps may be performed on wafer 101 subsequent to the view shown in FIG. 9. For example, openings may be made in passivation layer 137 to expose bond pads in the last metal interconnect layer of layer 125. Barrier layers and capping structures (e.g. aluminum) may be formed over the bond pads. The wafer is then singulated to form individual integrated circuits, each including multiple transistors similar to transistor 115.

In some embodiments, providing a conductive structure in electrical contact with the body through the insulating layer may reduce the area needed for biasing the body of a transistor. Consequently, with some embodiments, additional active area outside of the gate and source drain regions of a transistor is not needed for body biasing.

In other embodiments, opening 501 in layer 105 may be formed at other times in the processing of wafer 101. For example, opening 501 may be formed after forming gate 117 (and forming the source/drain silicides and gate silicides) but prior to forming source/drain contacts 121 and 119 and prior to forming gate contact 118. Remaining structures of layer 108 and layers 123 and 125 would be formed after the removal substrate 201. With other embodiments, opening 501 may be formed prior to the formation of gate 117. In some embodiments, opening 501 may be formed prior to the formation of layer 123 but after the formation of layer 108. In one embodiment where the gate is formed before the body contact, the high temperature processing to form the transistor including the gate is first performed before the metal of interconnect 803 is formed. In some embodiments, some of the metal interconnect layers of layer 125 may be formed prior to forming opening 501, with the other metal interconnect layers being formed after the removal of substrate 201.

In other embodiments, polysilicon may be used to fill opening 501 and for interconnect 803. In such embodiments, after the formation of spacers 601 and 603 (see FIG. 6), a layer polysilicon (e.g. doped polysilicon) may be deposited over the backside of wafer 101 and then patterned to form the desired contact structures and interconnects. In one embodiment, the polysilicon is doped to be the same conductivity type as body 109.

In other embodiments, the transistors having their active regions in layer 107 may be bonded to another wafer having a second active layer with active regions for other transistors. With such embodiments, the resultant integrated circuit would have multiple active layers. The openings to the bodies of the transistors maybe formed prior to or subsequent to the bonding of the second wafer. In some embodiments, interconnect 803 is coupled to a body bias source located on the backside of wafer 101.

In one embodiment of the invention, a semiconductor device includes an active region including a body, a first source/drain region, and a second source/drain region of a transistor. The semiconductor device includes a gate of the transistor. The gate is located adjacent to the body with respect to a first side of the active region. The semiconductor device also includes an insulating layer located with respect to a second side of the active region. The active region is between the insulating layer and the gate. The semiconductor device also includes an opening through the insulating layer and a conductive structure in electrical contact with the body through the opening.

In another embodiment of the invention, a semiconductor device includes an active layer including an active region, a first source/drain region in the active region, and a second source/drain region in the active region. The semiconductor device also includes a body in the active region. The body is located between the first source/drain region and the second source/drain region. The semiconductor device also includes a gate adjacent to the body with respect to a first side of the active layer and an insulating layer adjacent to the body with respect to a second side of the active layer. The semiconductor device also includes a first opening through the insulating layer adjacent to the body and a first conductive structure in the first opening in electrical contact with the body.

In another embodiment of the invention, a method of making a semiconductor device includes forming a first layer with an active region. The active region includes a body of a transistor. The method also includes forming a gate located with respect to a first side of the first layer and forming an opening through an insulating layer adjacent to the body. The insulating layer is located with respect to a second side of the first layer. The method further includes forming conductive material in the opening.

In another embodiment of the invention, a method of making a semiconductor device includes providing a first layer having a first side and a second side and an insulating layer located with respect to the second side. The insulating layer is located between the first layer and a first substrate layer. The first layer including an active region with a transistor body. The method also includes forming a gate of a transistor located with respect to the first side of the first layer and forming a second substrate layer located with respect to the first side of the first layer. The method further includes removing the first substrate layer subsequent to the forming the second substrate layer, forming an opening through the insulating layer after the removing the first substrate layer, and forming conductive material in the opening. The conductive material is in electrical contact with the body.

While particular embodiments of the present invention have been shown and described, it will be recognized to those skilled in the art that, based upon the teachings herein, further changes and modifications may be made without departing from this invention and its broader aspects, and thus, the appended claims are to encompass within their scope all such changes and modifications as are within the true spirit and scope of this invention.

1. A semiconductor device, comprising:
an active region including a body, a first source/drain region, and a second source/drain region of a transistor;
a gate of the transistor, the gate located adjacent to the body with respect to a first side of the active region;
an insulating layer located with respect to a second side of the active region, wherein the active region is between the insulating layer and the gate;
an opening through the insulating layer; and
a conductive structure in electrical contact with the body through the opening.

2. The semiconductor device of claim 1, wherein the body is doped to a first conductivity type and the conductive structure comprises polysilicon doped to the first conductivity type.

3. The semiconductor device of claim 1, wherein the conductive structure comprises metal.

4. The semiconductor device of claim 1, wherein the conductive structure comprises:
a barrier layer in the opening;
a fill material in the opening.

5. The semiconductor device of claim 1 wherein the conductive structure comprises an interconnect including a portion located with respect to an opposite side of the insulating layer from the active region.

6. The semiconductor device of claim 1, wherein the conductive structure comprises:
a barrier layer in the opening;
a fill material in the opening;
interconnect including a portion located with respect to an opposite side of the insulating layer from the active region.

7. The semiconductor device of claim 1, wherein the conductive structure comprises tungsten located in the opening.

8. The semiconductor device of claim 1 further comprising a sidewall spacer lining at least a portion of the opening.

9. The semiconductor device of claim 8, wherein the sidewall spacer is characterized as being non-conductive.

10. The semiconductor device of claim 9, wherein the conductive structure comprises:
a barrier layer adjacent to the sidewall spacer in the opening.

11. The semiconductor device of claim 10 wherein the conductive structure further comprises:
a fill material adjacent to the barrier layer in the opening.

12. The semiconductor device of claim 1 further comprising:
an interconnect layer spaced from the gate, wherein the active region is located in a first layer which is between the interconnect layer and the insulating layer, the interconnect layer including an interconnect for receiving a bias voltage;
a second opening through the insulating layer; and
a second conductive structure located in the second opening, the second conductive structure is electrically coupled between the interconnect and the conductive structure.

13. The semiconductor device of claim 12, further comprising an isolation region in the first layer, wherein the second opening passes through the isolation region.

14. The semiconductor device of claim 1 wherein the conductive structure is coupled to a body bias source.

15. The semiconductor device of claim 14, wherein the body bias source is coupled to a voltage supply at a ground voltage.

16. The semiconductor device of claim 14, wherein the body bias source is coupled to a voltage supply at a non ground voltage.

17. The semiconductor device of claim 14, wherein a voltage of the body bias source is variable during an operation of the transistor.

18. The semiconductor device of claim 1, wherein the opening through the insulating layer is located at a position that is between the first source/drain region and the second source/drain region.

19. A semiconductor device comprising:
an active layer including an active region;
a first source/drain region in the active region;
a second source/drain region in the active region;
a body in the active region, the body is located between the first source/drain region and the second source/drain region;
a gate adjacent to the body with respect to a first side of the active layer;
an insulating layer adjacent to the body with respect to a second side of the active layer;
a first opening through the insulating layer adjacent to the body; and
a first conductive structure in the first opening in electrical contact with the body.

20. The semiconductor device of claim 19, further comprising:
an interconnect layer spaced from the gate with respect to the first side of the active layer;
an isolation region in the active layer;
a second opening through the isolation region and the insulating layer;
a second conductive structure in the second opening; and
a third conductive structure electrically coupling the first conductive structure and second conductive structure.

21. The semiconductor device of claim 20, wherein the second opening has at least a portion lined with a sidewall spacer.

22. The semiconductor device of claim 20 wherein the second conductive structure includes a barrier layer.

23. The semiconductor device of claim 19, wherein the first opening has at least a portion lined with a sidewall spacer.

24. The semiconductor device of claim 19, wherein the first conductive structure comprises at least one of a group consisting of titanium nitride, titanium, tantalum, tungsten, and doped polysilicon.

25. The semiconductor device of claim 19 wherein a first conductive structure is electrically coupled to a body bias source for applying a reference voltage to the body.

26. The semiconductor device of claim 25, wherein the body bias source is electrically coupled to a voltage supply at a ground voltage.

27. The semiconductor device of claim 25, wherein the body bias source is electrically coupled to a voltage supply at a non ground voltage.

28. The semiconductor device of claim 25, wherein a voltage of the body bias source is variable during an operation of the semiconductor device.

29. The semiconductor device of claim 19, wherein:
the active layer includes an isolation region surrounding the active region.

30. A method of making a semiconductor device, comprising:
forming a first layer with an active region, the active region including a body of a transistor;
forming a gate located with respect to a first side of the first layer,
forming a a first opening through an insulating layer adjacent to the body, the insulating layer located with respect to a second side of the first layer;
forming conductive material in the first opening;
forming a second opening laterally of set from the first opening through the insulating layer located with respect to the second side of the first layer;
forming conductive material in the second opening; and
forming a conductive structure electrically coupled between the conductive material in the first opening and the conductive material in the second opening to enable coupling of the body of the transistor to a bias source via the second opening.

31. A method of claim 30 wherein the forming the first layer with the active region further comprises:
providing a semiconductor layer;
forming a first isolation region in the semiconductor layer to define the active region in the semiconductor layer.

32. The method of claim 30 further comprising lining at least a portion of the opening with a sidewall spacer prior to the forming the conductive material.

33. The method of claim 32, wherein the sidewall spacer is non-conductive.

34. The method of claim 30 wherein the conductive material includes a barrier layer material.

35. The method of claim 30 wherein the conductive material includes tungsten.

36. (canceled)

37. The method of claim 30, wherein the forming the gate is performed prior to the forming the opening.

38. The method of claim 30, further comprising implanting into the active region through the opening.

39. The method of claim 38, further comprising lining at least a portion of the opening after the implanting.

40. The method of claim 30 wherein the forming conductive material includes forming a barrier layer in the opening.

41. A method of making a semiconductor device, comprising:
providing a first layer having a first side and a second side and an insulating layer located with respect to the second side, the insulating layer located between the first layer and a first substrate layer, the first layer including an active region with a transistor body;
forming a gate of a transistor located with respect to the first side of the first layer;
forming a second substrate layer located with respect to the first side of the first layer;
removing the first substrate layer subsequent to the forming the second substrate layer;
forming a first opening through the insulating layer after the removing the first substrate layer;
forming conductive material in the first opening, the conductive material in electrical contact with the transistor body; and
forming a second opening laterally offset from the first opening through the insulating layer;
forming conductive material in the second opening; and
forming a conductive structure electrically coupled between the conductive material in the first opening and the conductive material in the second opening to enable coupling of the transistor body to a bias source via the second opening.

42. The method of claim 41 further comprising:
after the forming conductive material in the opening, forming a third substrate layer located with respect to the second side of the first layer, the insulating layer located between the first layer and the third substrate layer; and
removing the second substrate layer after the forming the third substrate layer.

43. The method of claim 41, further comprising lining at least a portion of the opening with a non conducting sidewall spacer prior to forming conductive material in the opening.

44. The method of claim 41 further comprising:
forming a first interconnect layer located with respect to the first side of the first layer after the forming the gate and prior to the removing the first substrate layer.

45. The method of claim 41 wherein the forming the gate is performed prior to the forming the second substrate layer.

46. The method of claim 41 wherein the conductive material includes tungsten.
